(19) United States
(12) Patent Application Publication
(10) Pub. No.: US 2017/0163409 A1
(43) Pub. Date: Jun. 8, 2017

(54) PHASE SYNCHRONIZATION CIRCUIT AND PHASE SYNCHRONIZATION METHOD

(71) Applicant: FUJITSU LIMITED, Kawasaki-shi (JP)

(72) Inventor: HIRONOBU HONGOU, Sendai (JP)

(21) Appl. No.: 15/346,321

(22) Filed: Nov. 8, 2016

(30) Foreign Application Priority Data
Dec. 8, 2015 (JP) 2015-239695

(51) Int. Cl. H04L 7/033; H03L 7/099; H03L 7/093

(52) U.S. Cl. CPC H04L 7/0331; H03L 7/093; H03L 7/0992

(57) ABSTRACT

There is provided a phase synchronization circuit including: a generation circuit to which an input clock signal is input, and configured to shift the input clock signal by intervals at which numbers of clocks of the input clock signal become equal so as to generate a plurality of pulse signals; a plurality of counter circuits each configured to measure pulse intervals of each of the plurality of pulse signals generated by the generation circuit, respectively; an average value calculation circuit configured to calculate an average value of measured values by the plurality of counter circuits; a frequency calculation circuit configured to calculate a frequency of the input clock signal from the average value calculated by the average value calculation circuit; and a phase locked loop (PLL) circuit configured to perform a phase synchronization processing on the input clock signal, based on the frequency calculated by the frequency calculation circuit.

### CROSS-REFERENCE TO RELATED APPLICATION

This application is based upon and claims the benefit of priority of the prior Japanese Patent Application No. 2015-239695, filed on Dec. 8, 2015, the entire contents of which are incorporated herein by reference.

### FIELD

The embodiments discussed herein are related to a phase synchronization circuit and a phase synchronization method.

### BACKGROUND

A phase locked loop (PLL) circuit generates a clock signal having a phase synchronized with an input signal by a feedback control using an oscillator such as a voltage-controlled oscillator (VCO) (e.g., Japanese Laid-Open Patent Publication No. 6-132815). The PLL circuit is used as a unit for reproducing a clock signal from a received data signal in a communication device such as an optical transmission device.

The phase synchronization processing within a short period of time is required in the PLL circuit of a communication device in order to reduce a communication interruption time, for example, at the time of a start-up of a communication device or a switching of a communication line. For that reason, the PLL circuit operates by switching a cut-off frequency, that is, by switching a response characteristic of a built-in loop filter. For example, the PLL circuit initially sets the cut-off frequency to 100 Hz in order to respond at a relatively high speed to be generally synchronized with a target frequency, and then, sets the cut-off frequency to 1 Hz in order to stabilize the frequency.

For example, similarly to a frame signal of the Ethernet (registered trademark, the same hereinafter), when a gap exists between input signals, the frequency to be set for the oscillator largely varies, by the influence of the gap in the PLL circuit, as the cut-off frequency increases. Accordingly, the frequency largely changes after the switching of the cut-off frequency, and thus, the time required for the phase synchronization processing of the signals between which a gap exists increases, as compared to signals between which no gap exists.

In this regard, for example, Japanese Laid-Open Patent Publication No. 2013-197808 discloses a technique which shortens the time required for the phase synchronization processing by averaging phases of signals input to the PLL circuit to suppress the frequency variation after the switching of the cut-off frequency.

### SUMMARY

According to an aspect of the invention, a phase synchronization circuit includes: a generation circuit to which an input clock signal is input, and configured to shift the input clock signal by intervals at which numbers of clocks of the input clock signal become equal so as to generate a plurality of pulse signals; a plurality of counter circuits each configured to measure pulse intervals of each of the plurality of pulse signals generated by the generation circuit, respectively; an average value calculation circuit configured to calculate an average value of measured values by the plurality of counter circuits; a frequency calculation circuit configured to calculate a frequency of the input clock signal from the average value calculated by the average value calculation circuit; and a phase locked loop (PLL) circuit configured to perform a phase synchronization processing on the input clock signal, based on the frequency calculated by the frequency calculation circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an exemplary configuration of a phase synchronization circuit;

FIG. 2A and FIG. 2B are graphs illustrating a variation in signals depending on a cut-off frequency;

FIG. 3 is a graph illustrating situations of convergence of signals in a loop filter;

FIG. 4 is a diagram illustrating an exemplary configuration of a measurement circuit;

FIG. 5 is a time chart illustrating an exemplary operation of the measurement circuit;

FIG. 6 is a time chart illustrating a comparative example of a frequency measurement scheme for an input clock signal;

FIG. 7A and FIG. 7B are graphs illustrating simulation results of a frequency accuracy in a comparative example and the embodiment;

FIG. 8 is a table illustrating simulation results of the frequency accuracy for each period in the comparative example and an embodiment;

FIG. 9 is a flowchart illustrating an exemplary operation of a phase synchronization circuit;

FIG. 10 is a diagram illustrating another exemplary configuration of a phase synchronization circuit;

FIG. 11 is a diagram illustrating another exemplary configuration of a measurement circuit, and

FIG. 12 is a diagram illustrating an exemplary configuration of a memory.

### DESCRIPTION OF EMBODIMENTS

According to the technique of averaging the phases of the signals input to the PLL circuit, the time required for the phase synchronization processing depends on the response characteristics of the PLL circuit and thus becomes longer as a difference between a frequency of an oscillator and a frequency of an input signal increases. This is because a capacitor charge time is needed until a voltage inside a loop filter reaches a value corresponding to a target frequency in the phase synchronization processing. For that reason, the time required for the phase synchronization processing may not be reduced effectively.

Hereinafter, descriptions will be made on embodiments of the technique capable of reducing the time required for the phase synchronization processing with reference to the accompanying drawings.

### First Embodiment

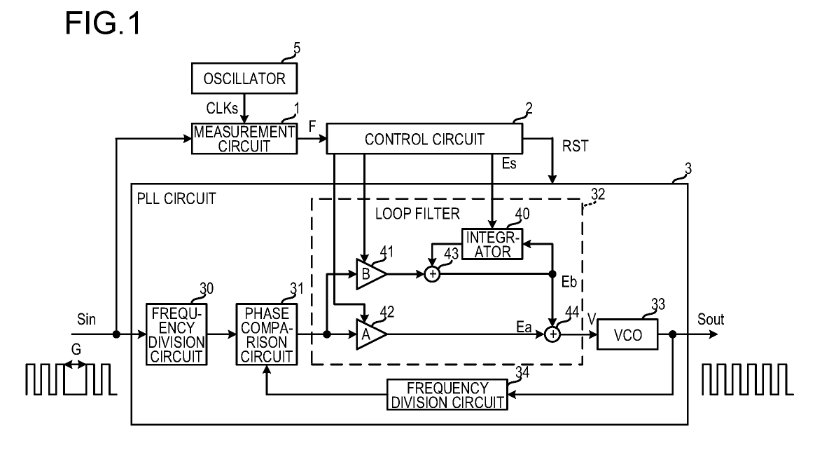

FIG. 1 is a diagram illustrating an exemplary configuration of a phase synchronization circuit. The phase synchronization circuit includes a measurement circuit 1, a control circuit 2, a PLL circuit 3, and an oscillator 5. The PLL circuit 3 includes frequency division circuits 30 and 34, a phase comparison circuit 31, a loop filter 32, and a voltage-controlled oscillator (VCO) 33.

The PLL circuit 3 generates an output clock signal Sₒᵤₜ, of which a phase is synchronized with an input clock signal Sᵢₙ, from a VCO 33 by a feedback control. The frequency division circuit 30 divides the frequency of the input clock signal Sᵢₙ. The frequency-divided input clock signal S is input to the phase comparison circuit 31.

The phase comparison circuit 31 detects a phase difference between the input clock signal Sᵢₙ and the output clock signal Sₒᵤₜ output from the VCO 33. More specifically, the phase comparison circuit 31 detects a phase difference between the input clock signal Sᵢₙ and the output clock signal Sₒᵤₜ of which the frequency is divided by the frequency division circuit 34. The phase comparison circuit 31 generates a differential signal indicating the phase difference and outputs the differential signal to the loop filter 32.

The loop filter 32 is an example of a filter circuit and filters the differential signal input from the phase comparison circuit 31 to generate a control signal V. The generated control signal V is input to the VCO 33.

The VCO 33 generates the output clock signal Sₒᵤₜ of a frequency corresponding to a voltage of the control signal V input from the loop filter 32. That is, the VCO 33 controls the frequency of the output clock signal Sₒᵤₜ based on the control signal V. The output clock signal Sₒᵤₜ generated in the VCO 33 is output to the outside of the phase synchronization circuit and used for data processing and others.

The output clock signal Sₒᵤₜ is fed back to the phase comparison circuit 31 through the frequency division circuit 34. The frequency division circuit 34 divides the frequency of the output clock signal Sₒᵤₜ and outputs the output clock signal Sₒᵤₜ to the phase comparison circuit 31. The frequency division circuits 30 and 34 perform the frequency-division by, for example, a counter circuit.

The loop filter 32 may include, for example, an infinite impulse response (IIR) filter, but is not limited thereto, and include other digital filters. The loop filter 32 includes an integrator 40, multipliers 41 and 42, and adders 43 and 44. The configuration of the loop filter 32 illustrated in FIG. 1 corresponds to a simplified circuit configuration of the loop filter 32.

The multiplier 42 constitutes a feedforward system of the IIR filter and a tap coefficient A is set for the multiplier 42. The multiplier 42 generates a signal Ea by multiplying the differential signal output from the phase comparison circuit 31 by the tap coefficient A. The signal Ea is input to the adder 44.

The multiplier 41, the adder 43, and the integrator 40 constitute a feedback system of the IIR filter. A tap coefficient B is set for the multiplier 41, and the multiplier 41 generates a signal by multiplying the differential signal output from the phase comparison circuit 31 by the tap coefficient B and output the generated signal to the adder 43. The adder 43 adds a signal input from the integrator 40 to the signal input from the multiplier 41 to generate a signal Eb. The signal Eb is input to the integrator 40 and the adder 44.

The integrator 40 delays the signal Eb and outputs the delayed signal Eb to the adder 43. The integrator 40 includes a capacitor component, and controls a delay time by saving and discharging the charge.

The adder 44 adds the signal Ea of the feedforward system and the signal Eb of the feedback system to generate a control signal V. The control signal V is input to the VCO 33.

The control circuit 2 sets the tap coefficients A and B of the multipliers 41 and 42, respectively, so as to control a cut-off frequency fc, that is, a response characteristic of the loop filter 32. The PLL circuit 3 may perform phase synchronization in a short period of time as the cut-off frequency fc increases.

However, when the input clock signal Sin includes a gap G between signals, for example, as in the frame signal of the Ethernet, the signal Eb of the loop filter 32 largely varies by the influence of the gap G in the PLL circuit as the cut-off frequency fc increases.

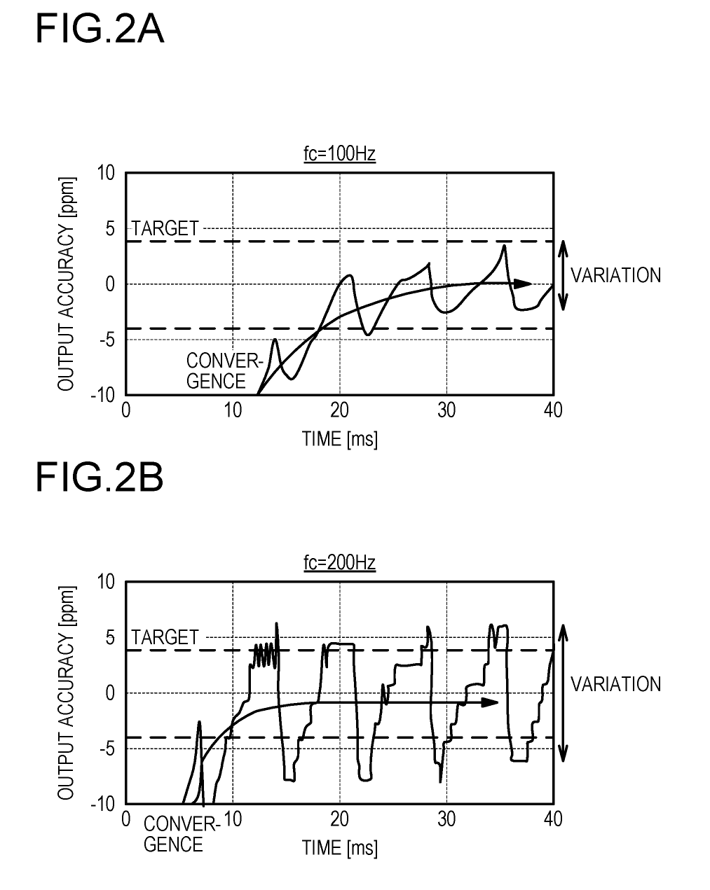

FIGS. 2A and 2B illustrate a variation of the signal Eb depending on the cut-off frequency fc. FIG. 2A and FIG. 2B illustrate simulation results of a temporal change (ms) of output accuracy (ppm) of the signal Eb in a case where the cut-off frequency fc is set as 100 Hz and in a case where the cut-off frequency fc is set as 200 Hz, respectively.

As understood from the comparison of the simulation results for the cases of fc=100 Hz and fc=200 Hz, the time required for the convergence of the signal Eb to the target for the case of fc=200 Hz is shorter than that for the case of fc=100 Hz. However, the variation of the signal Eb for the case of fc=200 Hz is larger than that for the case of fc=100 Hz.

That is, a response speed of the loop filter 32 and a degree of the influence of the gap G have a contrary relationship with each other. For that reason, in a case where the input clock signal Sᵢₙ includes the gap G, the time required for phase synchronization, that is, the time required for frequency pull-in becomes longer than a case where the input clock signal Sᵢₙ do not include the gap G.

The time required for phase synchronization is influenced by the charge time for the capacitor component of the integrator 40 taken until the voltage of the signal Eb of the loop filter 32 reaches a value corresponding to a target value of the frequency of the output clock signal Sₒᵤₜ.

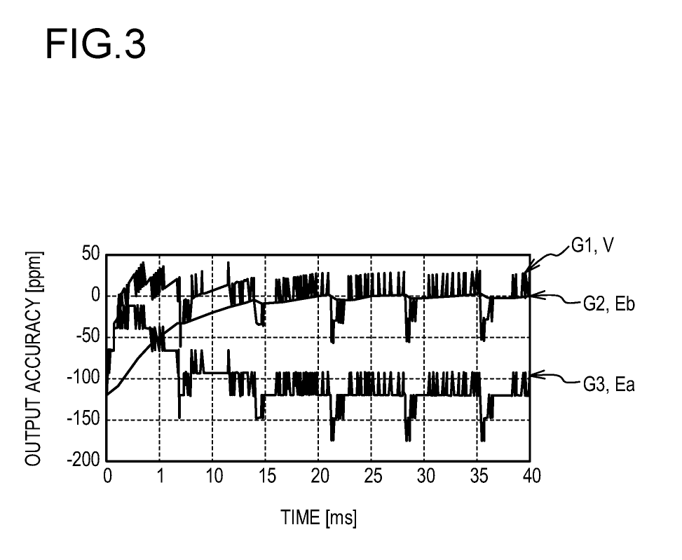

FIG. 3 is a graph illustrating situations of the convergence of the signals Ea, Eb, and V in the loop filter 32. In FIG. 3, the reference numeral G1 indicates the control signal V, and the reference numeral G2 (see thick line) indicates the signal Eb. The reference numeral G3 indicates the signal Ea. That is, FIG. 3 illustrates the temporal change (ms) in the output accuracy (ppm) of voltages of the signals Ea and Eb and the control signal V.

As understood from FIG. 3, the convergence of the voltage of the signal Eb is slower than that of the signal Ea due to the charge time for the capacitor component of the integrator 40. For that reason, the convergence of the control signal V is also delayed, and thus, the time required for phase synchronization increases. In addition, FIG. 3 illustrates the simulation result for a case where the cut-off frequency fc=100 Hz and the gap G is present in the input clock signal Sᵢₙ.

Thus, the measurement circuit 1 measures the frequency of the input clock signal Sᵢₙ, and the control circuit 2 sets the integrator 40 to the voltage Es corresponding to the measured value F so as to reduce the time required for the convergence of the signal Eb. Accordingly, the time required for phase synchronization is reduced.

When the operation of the phase synchronization circuit is started (e.g., when a power is turned ON), the measurement circuit 1 measures the frequency of the input clock signal Sin based on a system clock signal CLKs input from the oscillator 5 and outputs the measured value F to the control circuit 2. The control circuit 2 converts the measured value F of the frequency into a voltage Es, generates a signal of the voltage Es, and outputs the signal to the integrator 40. Therefore, the integrator 40 does not need to charge the capacitor component, and thus, the convergence time of the signal Eb is reduced.

In addition, the control circuit 2 sets the tap coefficients A and B for the multipliers 41 and 42 such that the cut-off frequency fc of the loop filter 32 is, for example, 1 Hz after setting the voltage Es, and generates a reset signal RST resetting the PLL circuit 3. Accordingly, the counter values of the frequency division circuits 30 and 34 are initialized, and frequency division is started from an initial phase state. Thus, a stable phase synchronization is started from a state where the frequency of the output clock signal Sₒᵤₜ is set to the target value.

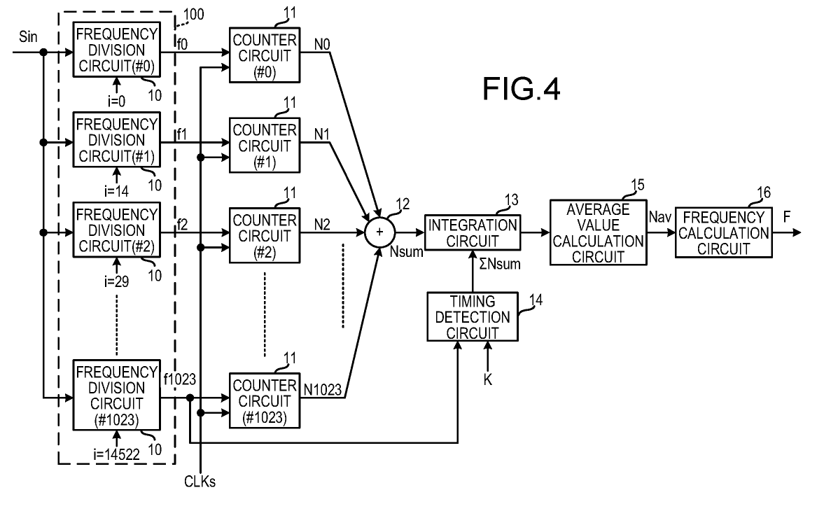

FIG. 4 is a diagram illustrating an exemplary configuration of a measurement circuit 1. The measurement circuit 1 includes a pulse generation circuit 100, a plurality of counter circuits (#0 to #1023) 11, an adder 12, an integration circuit 13, a timing detection circuit 14, an average value calculation circuit 15, and a frequency calculation circuit 16.

The pulse generation circuit 100 is an example of a generation circuit. The pulse generation circuit 100 shifts the input clock signals Sᵢₙ by intervals at which the numbers of clocks of the input clock signal Sᵢₙ become equal so as to generate the plurality of pulse signals f0 to f1023. More specifically, the pulse generation circuit 100 includes the plurality of frequency division circuits (#0 to #1023) 10 each dividing the frequency of the input clock signal Sᵢₙ. Each of the plurality of frequency division circuits 10 starts frequency division at a timing corresponding to each setting value i so as to shift the input clock signal Sᵢₙ by intervals at which the numbers of clocks of the input clock signal Sᵢₙ become equal. Accordingly, the gaps G that are irregularly distributed in various locations within the input clock signals Sᵢₙ may be included widely throughout the plurality of pulse signals f0 to f1023, and thus, the influence by the gap G of the input clock signals Sᵢₙ is easily reduced.

The frequency division circuit 10 divides the frequency of the input clock signal Sᵢₙ by a counter circuit built in the frequency division circuit 10 (hereinafter, denoted as a “built-in counter”). The setting value i indicates an initial value of a built-in counter when the frequency division is started, that is, an initial value of the counter value. In the first embodiment, the number of the counter circuits 11 and the frequency division circuits 10 is 1024, but the number is not limited thereto.

For example, the frequency division circuit (#0) 10 starts frequency division by setting the counter value to 0, and the frequency division circuit (#1) 10 starts frequency division by setting the counter value to 14. The setting values i are determined to be shifted equally between the pulse signals f0 and f1023. The pulse intervals of the pulse signals f0 to f1023 are not constant due to the irregularity of the distribution of the gaps G within the input clock signal Sᵢₙ. However, each of the plurality of counter circuits 11 measures each of the pulse intervals varying according to the distribution of the gap G, and thus, the influence by the irregularly distributed gaps G is reduced.

i=INT[{(1024−n)/1024}×14536] (1)

For example, in a case where the frequency division circuit 10 performs a frequency division of a frequency division number 14536, the setting value i of each of the frequency division circuits (#0 to #1023) 10 is calculated from the Equation (1) described above. In the Equation (1), INT is a function that discards decimal numbers, and n is an identification number of the frequency division circuit 10 (#1 to #1023).

The plurality of frequency division circuits (#0 to #1023) 10 outputs the pulse signals f0 to f1023 to the plurality of counter circuits (#0 to #1023) 11, respectively. The plurality of counter circuits 11 measures the pulse intervals of the plurality of pulse signals f0 to f1023 based on the system clock signal CLKs, respectively.

The counter circuit 11 counts the lengths between adjacent pulses of the pulse signals f0 to f1023 by the system clock signal CLKs to measure the pulse interval. Each of the plurality of counter circuits (#0 to #1023) 11 outputs each of the measured values N0 to N1023 of the pulse intervals of the pulse signals f0 to f1023 to the adder 12.

The adder 12 calculates a sum-up value Nₛᵤₘ by adding the measured values N0 to N1023 of the pulse intervals and outputs the sum-up value to the integration circuit 13. The integration circuit 13 integrates the sum-up values Nₛᵤₘ for K periods and outputs the integrated Nₛᵤₘ to the average value calculation circuit 15.

The timing detection circuit 14 notifies the integration circuit 13 of an integration timing of the sum-up value Nₛᵤₘ. The number of periods K to be integrated is set in the timing detection circuit 14, and the timing detection circuit 14 counts the number of pulses of the pulse signal f1023 having the latest phase among the plurality of pulse signals f0 to f1023, and notifies the integration circuit 13 of the integration timing when the number of the counted pulses reaches K.

The integration circuit 13 integrates the sum-up values Nₛᵤₘ each time the sum-up value Nₛᵤₘ is input from the adder 12 and outputs the integrated sum-up value ΣNₛᵤₘ to the average value calculation circuit 15 according to the notification from the timing detection circuit 14. Accordingly, the integration circuit 13 integrates the sum-up values Nₛᵤₘ for K periods.

The average value calculation circuit 15 calculates an average value Nₐᵥ of the respective measured values N0 to N1023 for K periods of the plurality of counter circuits 11. More specifically, the average value calculation circuit 15 calculates the average value Nₐᵥ by dividing the integrated value ΣNₛᵤₘ by 1024 which is the number of the counter circuits 11.

F=K·Fs/Nₐᵥ (2)

The frequency calculation circuit 16 calculates the frequency F (measured frequency value F) of the input clock signal Sᵢₙ from the average value Nₐᵥ. The frequency calculation circuit 16 calculates the frequency F from, for example, the Equation (2) above. In the Equation (2), the numerical value Fs represents a frequency of the system clock signal CLKs.

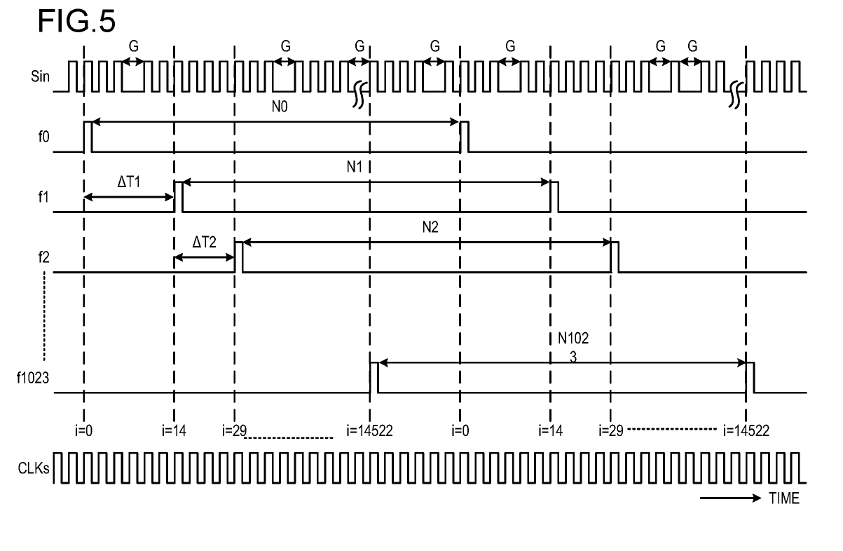

FIG. 5 is a time chart illustrating an exemplary operation of the measurement circuit 1. The plurality of frequency division circuits 10 starts a frequency division of the input clock signal Sᵢₙ at timings according to individual setting values i, respectively, as described above. Accordingly, the plurality of frequency division circuits 10 may easily generate the plurality of pulse signals f0 to f1023 of which the phases of pulses are shifted by a constant counter value of the built-in counter.

For example, the frequency division circuit (#0) 10 of FIG. 4 starts a frequency division of the input clock signal Sᵢₙ from the counter value=0 based on the setting value i=0 and generates the pulse signal f0. The frequency division circuit (#1) 10 starts a frequency division of the input clock signal Sᵢₙ from the counter value=14 based on the setting value i=14 and generates the pulse signal f1. The frequency division circuit (#2) 10 starts a frequency division of the input clock signal Sᵢₙ from the counter value=29 based on the setting value i=29 and generates the pulse signal f2.

In this manner, respective setting values i are equally shifted (=deviated) between the plurality of frequency division circuits 10, and thus, the phases of the pulses of the pulse signal f0 to f1023 are shifted by a constant counter value of the built-in counter. However, the gaps G are distributed at various positions in the input clock signals Sᵢₙ, and thus, the time intervals (e.g., see ΔT1 and ΔT2) of the pulses of the pulse signals f0 to f1023 do not become constant.

The plurality of counter circuits 11 measure the pulse intervals of the pulse signals f0 to f1023, respectively. More specifically, the counter circuit 11 counts the time intervals between adjacent pulses of the pulse signal f0 to f1023 by the system clock signal CLKs to measure the pulse interval. In the following, descriptions will be made on the advantages of the frequency measurement by the pulse interval measurement in the first embodiment by taking a comparative example.

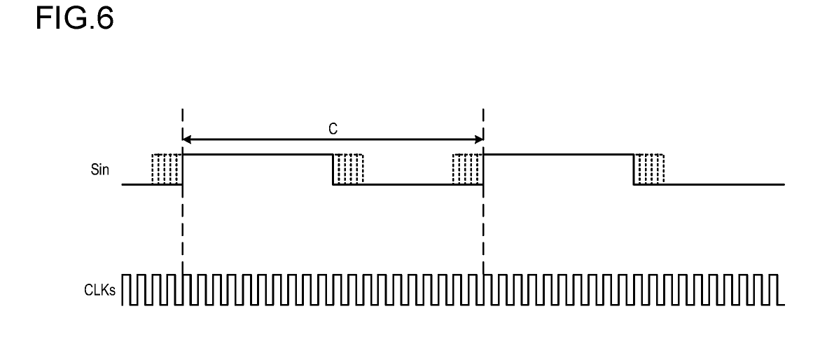

FIG. 6 is a time chart illustrating a comparative example of a frequency measurement scheme for the input clock signal Sᵢₙ. The frequency of the input clock signal Sᵢₙ is measured based on the number of counts (that is, the number of clocks) of the system clock signal CLKs within one period (see the reference numeral C) of the input clock signal Sᵢₙ.

F=K′·Fs/N′ (3)

The frequency F of the input clock signal Sᵢₙ is calculated from the Equation (3) above, for example, in a case where the number of counts N′ for K′ periods of the system clock signal CLKs is counted. Here, an amount of change per a single count of the number of counts N′ corresponds to the resolution of frequency measurement.

U={(N′+1)−N′}·10⁶/N′ (4)

Accordingly, the frequency accuracy U is calculated from, for example, the Equation (4) above. For example, when the number of counts N′ is approximately less than 100, the frequency accuracy is approximately 1 ppm.

The input clock signal Sᵢₙ includes the gap G, and thus, irregularities are present in positions of edges where counting of the number of counts N′ is started or ended as illustrated in dotted lines. For that reason, start timing and end timing of counting of the number of counts N′ are deviated, for example, in a range of ±10 every frequency measurement.

In this case, the number of counts N′ is deviated to the maximum of ±20. Therefore, for example, when the number of counts N′ is approximately less than 100, the frequency accuracy becomes approximately ±20 ppm, and thus, the resolution is reduced. In contrast, even when the frequency of the system clock signal CLKs is made higher, the variation amount merely increases, and thus, the resolution is not improved.

However, when a measurement time is extended to increase the number of counts N′, the resolution may be improved. For example, in a case where the number of counts N′ is approximately less than 2,000, the influence of the deviation is reduced, and thus, the frequency accuracy becomes approximately 1 ppm. However, in this case, when the frequency Fs is set to, for example 160 MHz, a measurement time of 125 ms is required to implement the frequency accuracy of approximately 1 ppm, and thus, it is difficult to implement the phase synchronization processing in a short timed.

In contrast, in the first embodiment, the plurality of frequency division circuits 10 start a frequency division of the input clock signal Sᵢₙ at different timings to generate the pulse signals f0 to f1023 of which the pulse positions are shifted. That is, the generation circuit 100 shifts the input clock signal Sᵢₙ by intervals at which the number of clocks of the input clock signal Sᵢₙ becomes equal so as to generate the plurality of pulse signals f0 to f1023. For that reason, the input clock signal Sᵢₙ, in which the irregularities (see, e.g., FIG. 6) at the edges of the input clock signal Sᵢₙ due to the influence by the gaps G are removed, is reproduced with high accuracy by the pulse signals f0 to f1023.

Furthermore, the plurality of counter circuits 11 are able to measure the pulse intervals of the pulse signals f0 to f1023 in parallel, and thus, the measurement time is reduced. In the first embodiment, although the plurality of counter circuits 11 measure the pulse interval every one period, the plurality of counter circuits 11 may measure the pulse intervals for K periods at one time. In this case, the integration processing by the integration circuit 13 becomes unnecessary.

The average value calculation circuit 15 calculates the average value Nₐᵥ of the measured values N0 to N1023 for the pulse intervals, and the frequency calculation circuit 16 calculates the frequency of the input clock signal Sᵢₙ from the average value Nₐᵥ. Accordingly, the measurement circuit 1 may reduce the influence of irregularity in the pulse positions, that is, the influence by the gaps G, and thus, may measure the frequency with high accuracy.

The plurality of counter circuits 11 measure the pulse intervals for K periods of the pulse signal f0 to f1023. That is, each of the plurality of counter circuits 11 measures the pulse interval several times. For that reason, the frequency resolution is improved as described with reference to FIG. 6. The number of measurement times by the counter circuit 11 may be performed once.

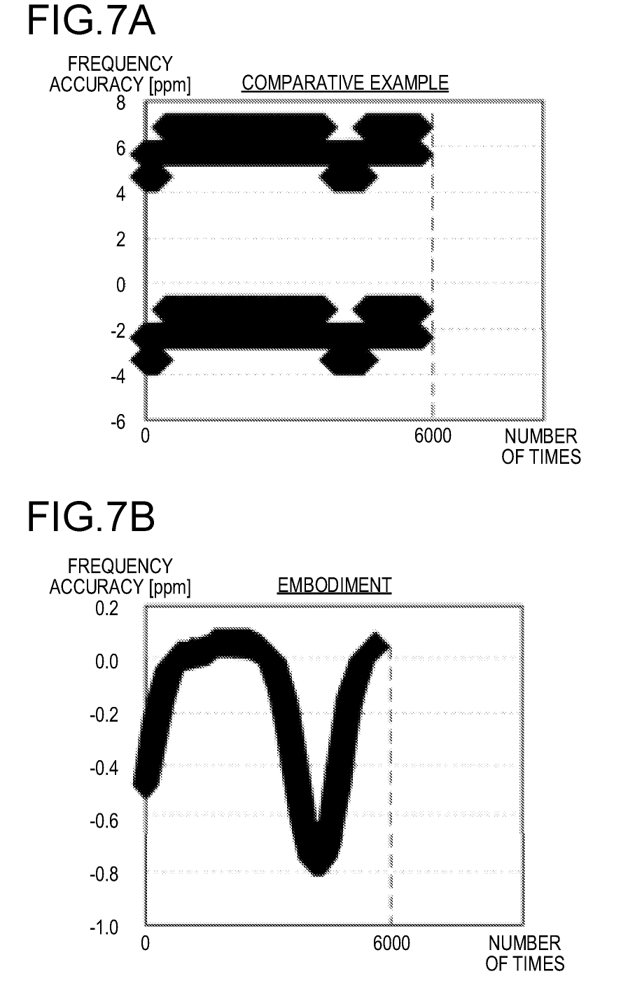

FIG. 7A and FIG. 7B are graphs illustrating simulation results of a frequency accuracy in a comparative example and the embodiment. In the comparative example of FIG. 7A, the frequency of the input clock signal Sᵢₙ is measured by the method illustrated in FIG. 6, and in the embodiment of FIG. 7B, the frequency of the input clock signal Sᵢₙ is measured by the configuration illustrated in FIG. 4. In the present simulation, as an example, the frequency of the input clock signal Sᵢₙ is set to 10 KHz, the number of measurement times (see “number of times”) is set to 6000 times, and the number of periods K for measurement is set to 64 periods.

As understood from the comparison of simulation results of the comparative example of FIG. 7A and the embodiment of FIG. 7B, a frequency accuracy which amounts to approximately ten times that of the comparative example of FIG. 7A may be obtained according to the embodiment of FIG. 7B.

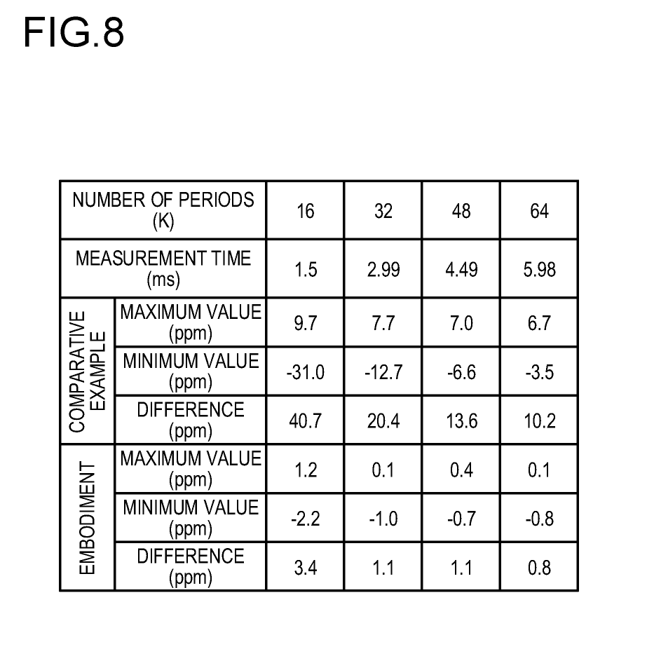

In FIG. 8, simulation results of the frequency accuracy for each period in the comparative example and the embodiment are illustrated. In the present simulation, as an example, the frequency of the input clock signal Sin is set to 10 KHz, and the numbers of periods K for measurement are set to 16 periods, 32 periods, 48 periods, and 64 periods. The numbers of periods K of 16 periods, 32 periods, 48 periods, and 64 periods correspond to 1.5 ms, 2.99 ms, 4.49 ms, and 5.98 ms, respectively, upon converting to measurement time.

FIG. 8 illustrates the maximum value, the minimum value, and a difference between the maximum value and the minimum value of the frequency accuracy in the comparative example and the embodiment. For example, when examining the 16 periods, the difference is reduced to 3.4 ppm in the embodiment while the difference is 40.7 ppm in the comparative example. The accuracy is improved in other number of periods according to the embodiment by more than that of the comparative example.

As described above, the measurement circuit 1 is able to measure the frequency of the input clock signal Sᵢₙ at a relatively high speed and accuracy.

As described above, the control circuit 2 sets the integrator 40 of the loop filter 32 to the voltage Es according to the measured value F of the frequency measured in the measurement circuit 1. For that reason, the PLL circuit 3 performs the phase synchronization processing on the input clock signal Sin based on the frequency measured in the measurement circuit 1, regardless of the response characteristics of the loop filter 32, and thus, the time required for the phase synchronization processing is reduced.

More specifically, the loop filter 32 generates the control signal V based on the frequency measured in the measurement circuit 1. For that reason, the phase of the output clock signal Sₒᵤₜ of the VCO 33 may be synchronized with the input clock signal Sᵢₙ in a relatively short time.

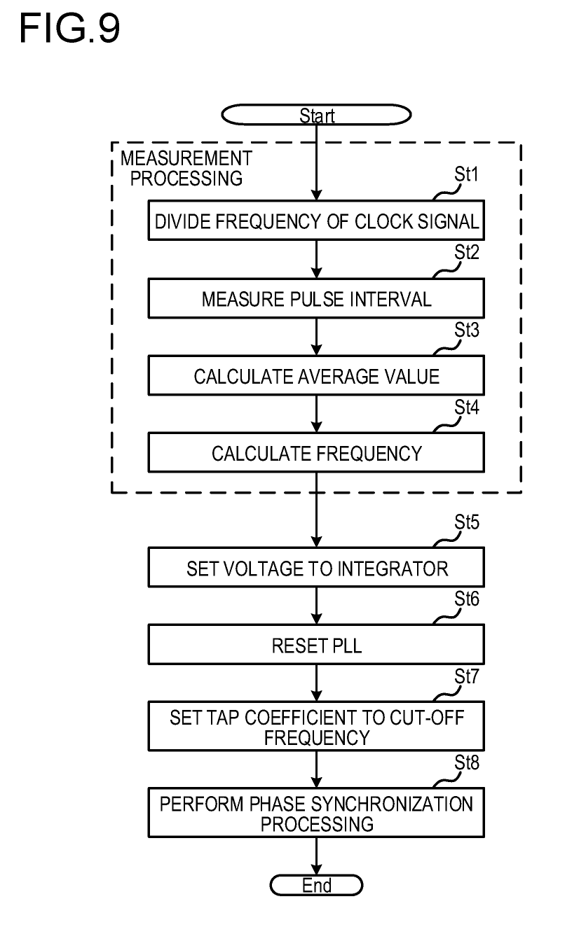

FIG. 9 is a flowchart illustrating an example of operations of a phase synchronization circuit. In FIG. 9, Operations St1 to St4 correspond to the frequency measurement processing of the input clock signal Sᵢₙ in the measurement circuit 1. The control circuit 2 may control to stop an operation of the PLL circuit 3 using, for example, the reset signal RST while the measurement circuit 1 performs the frequency measurement processing.

The measurement circuit 1 measures the pulse intervals for 16 periods based on, for example, the simulation result of FIG. 8. In this case, the frequency accuracy becomes at least −2.2 ppm, and thus, the phase synchronization may be performed with a sufficient high accuracy.

First, the plurality of frequency division circuits 10 divide the frequency of the input clock signal Sᵢₙ at start timings according to individual setting values i (Operation St1). Accordingly, the input clock signal Sᵢₙ is shifted by intervals at which the numbers of clocks become equal, and the plurality of pulse signals f0 to f1023 are generated.

Subsequently, the plurality of counter circuits 11 measure the pulse intervals of the plurality of pulse signals f0 to f1023, respectively (Operation St2). Subsequently, the average value calculation circuit 15 calculates the average value Nₐᵥ of each of the measured values N0 to N1023 for the pulse intervals (Operation St3). Subsequently, the frequency calculation circuit 16 calculates the frequency of the input clock signal Sᵢₙ from the average value Nₐᵥ (Operation St4).

The measurement circuit 1 outputs the measured value F of the frequency measured described above to the control circuit 2. In the meantime, the measurement time of the frequency is approximately 1.5 ms when referring to FIG. 8.

Subsequently, the control circuit 2 sets the integrator 40 of the loop filter 32 to the voltage Es of the measured value F of the frequency (Operation St5). Accordingly, the voltage value of the control signal V output from the loop filter 32 becomes a value according to the measured value F of the frequency, and thus, the phase of the output clock signal Sₒᵤₜ of the VCO 33 is rapidly synchronized with the input clock signal Sᵢₙ.

Subsequently, the control circuit 2 outputs the reset signal RST to the PLL circuit 3 to reset the PLL circuit 3 (Operation St6). Accordingly, phases of the frequency division circuits 30 and 34 are initialized.

Subsequently, the control circuit 2 sets the tap coefficients A and B to the multipliers 41 and 42 such that the cut-off frequency fc of the loop filter 32 becomes, for example, 1 Hz (Operation St7). Subsequently, the PLL circuit 3 performs the phase synchronization processing on the input clock signal Sᵢₙ based on the measured value F of the frequency (Operation St8).

In this manner, the PLL circuit 3 starts the phase synchronization processing at the cut-off frequency fc of 1 kHz after a time period of 1.5 ms for the frequency measurement. After the operation of the PLL circuit 3 is started, the control circuit 2 does not perform setting of the voltage Es to the integrator 40. After the measurement is ended, the operation of measurement of the measurement circuit 1 is stopped by the control of the control circuit 2.

In the first embodiment, the frequency measured by the measurement circuit 1 is used in the phase synchronization processing during the start-up of the phase synchronization circuit, but may also be used in a holdover for frequency after the start-up. The holdover refers to a function in which the phase synchronization is performed using a predetermined frequency acquired in advance in a case where the frequency is unable to be pulled from the input clock signal Sᵢₙ due to a failure. An embodiment for the case will be described in the following.

### Second Embodiment

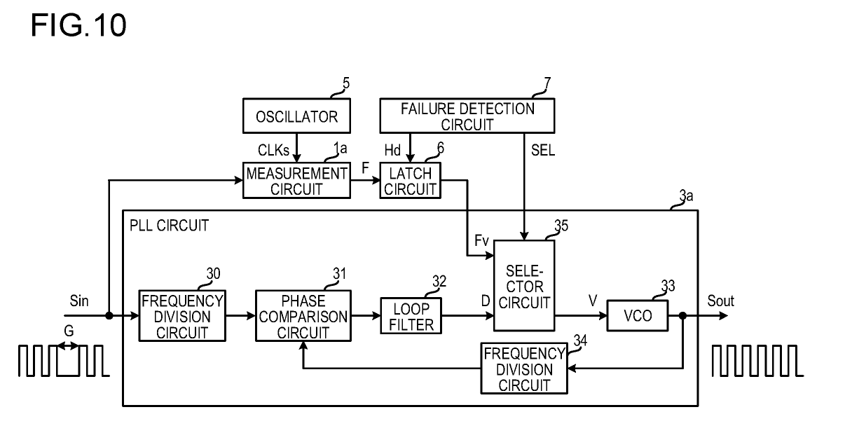

FIG. 10 is a diagram illustrating another exemplary configuration of a phase synchronization circuit. In FIG. 10, the same configurations as those of FIG. 1 will be denoted by the same reference numerals as used in FIG. 1, and descriptions thereof will be omitted.

The phase synchronization circuit includes a measurement circuit 1a, a latch circuit 6, a failure detection circuit 7, a PLL circuit 3a, and the oscillator 5. The PLL circuit 3a includes the frequency division circuits 30 and 34, the phase comparison circuit 31, the loop filter 32, the VCO 33, and a selector circuit 35.

Unlike in the previous embodiment, the measurement circuit 1a continues the frequency measurement of the input clock signal Sᵢₙ after the start-up of the phase synchronization circuit. For that reason, the measurement circuit 1a includes a unit for repeatedly maintaining the measured values N0 to N1023 of the pulse signals f0 to f1023 as described in the following.

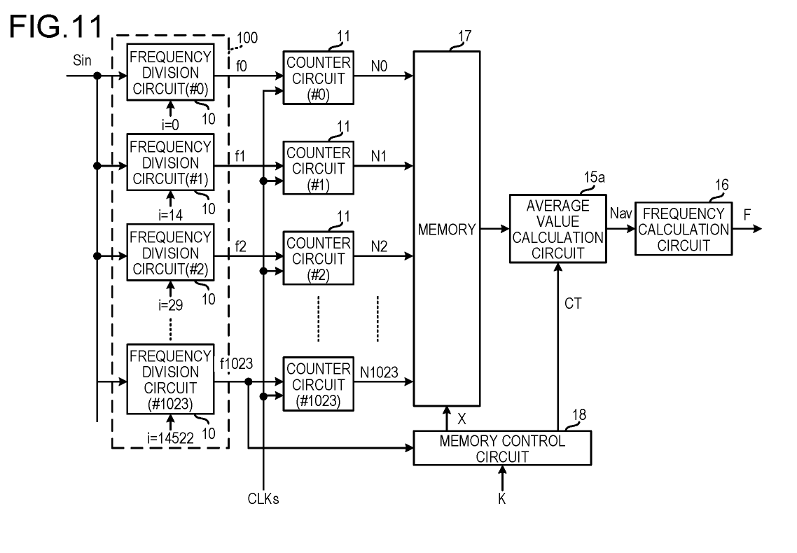

FIG. 11 is a diagram illustrating another exemplary configuration of a measurement circuit. In FIG. 11, the same configurations as those of FIG. 4 will be denoted by the same reference numerals as used in FIG. 4, and descriptions thereof will be omitted.

The measurement circuit 1a includes the pulse generating circuit 100 provided with the plurality of counter circuits 11, the plurality of counter circuits (#0 to #1023) 11, an average value calculation circuit 15a, the frequency calculation circuit 16, a memory 17, and a memory control circuit 18. Each time when measuring of the pulse interval is completed, the plurality of counter circuits 11 store the measured values N0 to N1023 in the memory 17, resets the counter value, and resumes the measurement. The memory 17 maintains the measured values N0 to N1023 of the pulse intervals for K periods measured by the counter circuit 11.

The memory control circuit 18 controls a recording target address, to which the measured value N0 to N1023 is to be recorded, within the memory 17 according to the periods of the pulse signals f0 to f1023. The memory control circuit 18 counts the number of pulses of the pulse signal f1023 so as to count the number of periods of the measured pulse interval. When the number of periods reaches the setting value K, the memory control circuit 18 resets the recording target address to an initial value. Accordingly, the measured values N0 to N1023 of the pulse intervals for K periods are repeatedly recorded in the memory 17.

The memory 17, as described in the following, stores the measured values N0 to N1023 in a storing area arranged two dimensionally as an example.

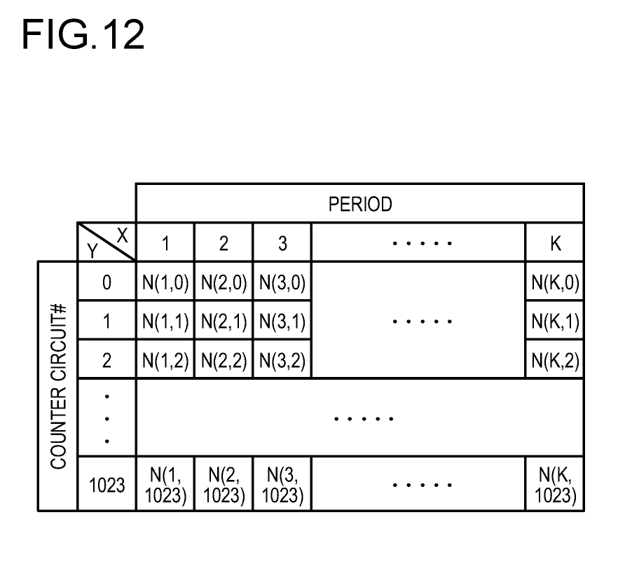

FIG. 12 is a diagram illustrating an exemplary configuration of the memory 17. The storing area of the memory 17 is specified by two addresses X and Y. When the measured values N0 to N1023 are recorded in the memory 17, the address X is determined according to the measurement period of 1 to K, and the address Y is determined according to an identification number of the counter circuit 11. The N(X,Y) indicates measured values N0 to N1023 stored in the addresses X and Y.

For example, a measured value NO measured by a counter circuit (#0) 11 at a first period is stored as N(1,0) in addresses X=1, Y=0, and a measured value N1 measured by a counter circuit (#1) 11 at the first period is stored as N(1,1) in addresses X=1, Y=1. A measured value NO measured by a counter circuit (#0) 11 at a second period is stored as N(2,0) in addresses X=2, Y=0, and a measured value N1 measured by a counter circuit (#1) 11 at the second period is stored as N(2,1) in addresses X=2, Y=1.

The address X is controlled by the memory control circuit 18. The memory control circuit 18 determines an address X to which the measured value N0 to N1023 is to be recorded according to the number of periods, and when the number of periods reaches a setting value K, the address X is reset to 0. Accordingly, the measured values NO to N1023 of the pulse intervals for K periods are repeatedly recorded in the memory 17.

Referring back to FIG. 11, when the number of periods reaches the setting value K, the memory control circuit 18 outputs a calculation instruction CT to the average value calculation circuit 15a. The average value calculation circuit 15a reads all measured values N(X,Y) from the memory 17 according to the calculation instruction CT and calculates the average value Nav.

$$Nav = {\sum }_{X = 1}^{K} {\sum }_{Y = 0}^{1023} N ( X , Y ) / 1024 \qquad ( 5 )$$

The average value calculation circuit 15a calculates the average value Nav from the Equation (5) above. That is, the average value calculation circuit 15a calculates the average value Nav by dividing all measured values N(X,Y) stored in the memory 17 by 1024, which is the number of counter circuits 11. The average value calculation circuit 15a outputs the calculated average value Nₐᵥ to the frequency calculation circuit 16. Accordingly, the measured value F of the frequency may be obtained.

Referring back to FIG. 10, the measurement circuit 1a outputs the measured frequency value F to the latch circuit 6. The latch circuit 6 maintains the measured frequency value F according to a holdover signal Hd from the failure detection circuit 7. The latch circuit 6 outputs a frequency signal Fv indicating the measured frequency value F maintained in the latch circuit 6 to the selector circuit 35.

The failure detection circuit 7 detects a failure within a device equipped with the phase synchronization circuit. When a failure is detected, the failure detection circuit 7 generates the holdover signal Hd and switches a signal value (e.g., 0 or 1) of a selection signal SEL to be output to the selector circuit 35.

The selector circuit 35 is an example of a selection circuit and selects one of a frequency signal Fv input from the latch circuit 6 and a differential signal D input from the loop filter 32 according to the signal value from the selection signal SEL. The differential signal D indicates a phase difference between the output clock signal Sₒᵤₜ and the input clock signal Sᵢₙ and is generated in the phase comparison circuit 31.

For example, when the signal value of the selection signal SEL is 0, the selector circuit 35 selects the differential signal D and outputs the differential signal D as the control signal V to the VCO 33. When the signal value of the selection signal SEL is 1, the selector circuit 35 selects the frequency signal Fv and outputs the frequency signal Fv as the control signal V to the VCO 33. The VCO 33 controls the frequency of the output clock signal Sₒᵤₜ based on the control signal V input from the selector circuit 35.

When no failure is detected, the failure detection circuit 7 sets the signal value of the selection signal SEL to 0. When a failure is detected, the failure detection circuit 7 sets the signal value of the selection signal SEL to 1. For that reason, when a failure occurs, the selector circuit 35 outputs the frequency signal Fv to the VCO 33. The VCO 33 generates the output clock signal Sₒᵤₜ of the frequency according to the frequency signal Fv. Accordingly, the measured value F of the measurement circuit 1a is used during the holdover.

Unlike the second embodiment, for example, the differential signals D output from the loop filter 32 may be averaged and output to the VCO 33 during the holdover. However, in this case, the PLL circuits 3 and 3a operate to coincide the phase difference of the input clock signal Sᵢₙ with that of the output clock signal Sₒᵤₜ even when the input clock signal Sᵢₙ is stabilized. Therefore, there is a problem that a shift occurs in the frequency of the output clock signal Sₒᵤₜ. In this case, the differential signal D is not able to be accumulated until the feedback control system of the PLL circuits 3 and 3a is stabilized, and thus, there is also a problem that the holdover function is not able to be executed.

In contrast, in the phase synchronization circuit of the second embodiment, the feedback control system of the PLL circuit 3 is separated during the holdover and uses a frequency measured with high accuracy in a short period of time by the measurement circuit 1a. Thus, the problem described above does not occur.

Furthermore, in the embodiments as described above, the input clock signal Sᵢₙ includes the gap G, however, the same effects as described above may be obtained even in a case of an input clock signal Sᵢₙ which does not include the gap G. Furthermore, the input clock signal Sᵢₙ may be obtained from an optical signal or an electrical signal, and is not limited thereto.

As having been described above, the phase synchronization circuit according to the embodiments includes the generation circuit 100, the plurality of counter circuits 11, the average value calculation circuits 15 and 15a, the frequency calculation circuit 16, and the PLL circuits 3 and 3a. The generation circuit 100 shifts the input clock signal Sᵢₙ by intervals at which the numbers of clocks of the input clock signal Sᵢₙ become equal to generate the plurality of pulse signals f0 to f1023. The plurality of counter circuits 11 measure the pulse intervals of the plurality of pulse signals f0 to f1023, respectively.

The average value calculation circuits 15 and 15a calculate the average value Nav of the measured values N0 to N1023 of the plurality of counter circuits 11. The frequency calculation circuit 16 calculates the frequency of the input clock signal Sin from the average value Nav. The PLL circuits 3 and 3a perform the phase synchronization processing on the input clock signal Sᵢₙ based on the frequency calculated by the frequency calculation circuit 16.

According to the configuration described above, the generation circuit 100 shifts the input clock signal Sᵢₙ by intervals at which the numbers of clocks of the input clock signal Sᵢₙ become equal to generate the plurality of pulse signals f0 to f1023. For that reason, the input clock signal Sᵢₙ, in which irregularities (see, e.g., FIG. 6) at the edges of the input clock signal Sᵢₙ due to the influence by the gaps G are removed, is reproduced with high accuracy by the pulse signal f0 to f1023.

Furthermore, the plurality of counter circuits 11 are able to measure the pulse intervals of the pulse signals f0 to f1023 in parallel, and thus, the measurement time of the input clock signal Sᵢₙ is reduced. The average value calculation circuit 15 calculates the average value Nₐᵥ of the measured values N0 to N1023 for the pulse interval, and the frequency calculation circuit 16 calculates the frequency of the input clock signal Sᵢₙ from the average value Nₐᵥ. For that reason, the influence by the gap G is reduced so as to make it possible to measure the frequency with a relatively high accuracy.

The PLL circuits 3 and 3a perform the phase synchronization processing on the input clock signal Sᵢₙ based on the frequency calculated by the frequency calculation circuit 16, regardless of the response characteristics of the loop filter 32, and thus, the time required for the phase synchronization processing is reduced.

The phase synchronization method according to the second embodiment includes the following operations.
Operation (1): The input clock signal Sᵢₙ is shifted by intervals at which the numbers of clocks of the input clock signal Sᵢₙ become equal to generate the plurality of pulse signals f0 to f1023.
Operation (2): Each of the pulse intervals of the plurality of pulse signals f0 to f1023 is measured.
Operation (3): Each average value Nₐᵥ of the measured values is calculated.
Operation (4): The phase synchronization processing is performed on the input clock signal Sᵢₙ based on the calculated frequency.

The phase synchronization method according to the embodiments includes the same configuration as that of phase synchronization circuit, and thus, the same effects as the contents described above are achieved.

The embodiments described above are examples suitable for embodying the present disclosure. However, the present disclosure is not limited thereto and may be variously modified in a range that does not depart from the gist of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A phase synchronization circuit comprising:
a generation circuit to which an input clock signal is input, and configured to shift the input clock signal by intervals at which numbers of clocks of the input clock signal become equal so as to generate a plurality of pulse signals;
a plurality of counter circuits each configured to measure pulse intervals of each of the plurality of pulse signals generated by the generation circuit, respectively;
an average value calculation circuit configured to calculate an average value of measured values by the plurality of counter circuits;
a frequency calculation circuit configured to calculate a frequency of the input clock signal from the average value calculated by the average value calculation circuit; and
a phase locked loop (PLL) circuit configured to perform a phase synchronization processing on the input clock signal, based on the frequency calculated by the frequency calculation circuit.

2. The phase synchronization circuit according to claim 1,
wherein the generation circuit includes a plurality of frequency division circuits, and a frequency division circuit of the plurality of frequency division circuits is configured to divide the frequency of the input clock signal at a timing corresponding to an individual setting value so as to shift the input clock signal by intervals at which the numbers of clocks of the input clock signal become equal.

3. The phase synchronization circuit according to claim 1,
wherein each of the plurality of counter circuits measures the pulse interval several times.

4. The phase synchronization circuit according to claim 1,
wherein the PLL circuit includes
an oscillator circuit configured to generate an output clock signal having a frequency according to a control signal, and
a filter circuit configured to generate the control signal based on the frequency calculated by the frequency calculation circuit and a differential signal indicating a phase difference between the output clock signal and the input clock signal.

5. The phase synchronization circuit according to claim 1,
wherein the PLL circuit includes
an oscillator circuit configured to generate an output clock signal,
a filter circuit configured to filter a differential signal indicating a phase difference between the output clock signal and the input clock signal, and
a selector circuit configured to select one of a frequency signal indicating the frequency calculated by the frequency calculation circuit and the differential signal filtered by the filter circuit, and
wherein the oscillator circuit controls a frequency of the output clock signal, based on a signal selected by the selector circuit.

6. A phase synchronization method comprising:
shifting an input clock signal by intervals at which numbers of clocks of the input clock signal become equal so as to generate a plurality of pulse signals;
measuring pulse intervals of each of the plurality of pulse signals;
calculating an average value of the pulse intervals measured;
calculating a frequency of the input clock signal from the average value calculated; and
performing a phase synchronization processing on the input clock signal, based on the frequency calculated.

7. The phase synchronization method according to claim 6,
wherein the plurality of pulse signals are generated by dividing a frequency of the input clock signal at a timing corresponding to an individual setting value so as to shift the input clock signal by intervals at which the numbers of clocks of the input clock signal become equal.

8. The phase synchronization method according to claim 6,
wherein the pulse intervals are measured several times.

9. The phase synchronization method according to claim 6,
wherein an output clock signal of an oscillator is generated according to a control signal generated based on the frequency of the input clock signal calculated from the average value.

10. The phase synchronization method according to claim 6,
wherein an output clock signal of an oscillator is generated according to a signal selected between a frequency signal indicating the frequency of the input clock signal calculated from the average value and a differential signal indication a phase difference between the output clock signal and the input clock signal.
